(19) United States
(12) Patent Application Publication
(10) Pub. No.: US 2005/0104641 A1
(43) Pub. Date: May 19, 2005

(54) Schmitt trigger circuit realized with low-voltage devices for high-voltage signal application

(75) Inventors: Shih-Lun Chen, Hsinchu (TW); Ming-Dou Ker, Hsinchu (TW)

Correspondence Address: BRUCE H. TROXELL, SUITE 1404, 5205 LEESBURG PIKE, FALLS CHURCH, VA, 22041, US

(73) Assignee: ADMtek Incorporated

(21) Appl. No.: 10/790,842

(22) Filed: Mar. 3, 2004

(30) Foreign Application Priority Data
Nov. 18, 2003 (TW) 92132206

(51) Int. Cl. H03K 3/037

(52) U.S. Cl. 327/205

(57) ABSTRACT

The present invention relates to a Schmitt trigger circuit. The proposed Schmitt trigger circuit can receive the high-voltage input signal but it is consisted by only using the low-voltage devices with thin gate oxide. For example, it is implemented in a 0.13 μm 1V/2.5V Complementary Metal-Oxide Semiconductor (CMOS) process. However, it can be operated in the 3.3 V interface environment without causing the high-voltage-induced gate-oxide reliability problem. It is suitable for the I/O interface circuit to receive the high-voltage input signal and to reject the noise.

### FIELD OF THE INVENTION

The present invention relates to a Schmitt trigger circuit with low-voltage devices, and more particularly, to a Schmitt trigger circuit capable of receiving a high-voltage input signal, but being consisted by only using low-voltage devices with thin gate oxide. The present invention adapts a plurality of serial-connected Metal-Oxide Semiconductor Field Effect Transistors (MOSFET) to form a low-cost Schmitt trigger circuit capable of enduring 3.3V, instead of 2.5V.

### BACKGROUND OF THE INVENTION

As the development of the semiconductor process, the thickness of gate-oxide is becoming thinner such that the electronic device is more adapted to the high frequency and high speed environment. The same time that the core power supply voltage (VDD) is also decreasing, however, the board voltage (VCC) is still remaining at between 3.3V to 5V, such as PCI-X interface. Hence, the high-voltage stress across the gate oxide becomes a serious problem in deep submicron (DSM) processes. The I/O circuit must be designed carefully to avoid the high-voltage gate-oxide stress.

Refer to FIG. 1, which shows a conventional input buffer. As seen in FIG. 1, the input buffer 12 uses a Schmitt trigger circuit connecting to a pad 11 to receive the input signal and then using a level converter to convert the signal swing from VCC to VDD for transmitting to a core circuit 13. Please refer to FIG. 2A, which is a schematic diagram depicting the circuitry of the conventional Schmitt trigger circuit. As seen, transistors P1, P2, P3, N1, N2, and N3 are the I/O devices of high voltage (VDDQ). If VCC is equal to VDD, the Schmitt trigger circuit can operate without high-voltage gate-oxide stress. The transfer curve of the conventional Schmitt trigger circuit of FIG. 1, as seen in FIG. 2B, has better noise immunity than the conventional inverter. As input signal IN goes to VDD from GND, the threshold voltage of the conventional Schmitt trigger circuit is V_{H}, that is, the output signal OUT is pulled low as signal IN exceeds the threshold voltage V_{H}. As input signal IN goes to GND from VDD, the threshold voltage of the conventional Schmitt trigger circuit is V_{L}, that is, the output signal OUT is pulled high as signal IN is lower than the threshold voltage V_{L}. Thus, the noise immunity of the conventional Schmitt trigger circuit is increased.

Several modified Schmitt trigger circuits have been proposed. Please refer to FIG. 3, which shows a conventional Schmitt trigger circuit with controllable hysteresis. The extra bias voltage VB and N4 are used to control the two threshold voltage V_{L} and V_{H}. A multi layers Schmitt trigger circuit was reported to adjust the threshold voltages with reference to FIG. 4, which shows a two layers Schmitt trigger circuit.

However, the Schmitt trigger circuits have high-voltage gate-oxide problem if VCC is higher than VDDQ. For example, board voltage (VCC) is 3.3V and I/O (VDDQ) devices are 2.5V devices. The gate-source voltages and gate-drain voltages of transistors P1, P2, P3, N1, N2, and N3 in FIG. 2A will be larger than 2.5V. Thus, all devices in FIG. 2A have the high-voltage gate-oxide stress problem. In order to deal with the aforementioned problem, the present invention provides a Schmitt trigger circuit with low-voltage devices. For example, the proposed circuit can be implemented in a 0.13 μm 1V/2.5V Complementary Metal-Oxide Semiconductor (CMOS) process and operates in 3.3V environment.

### SUMMARY OF THE INVENTION

The primary object of the present invention is to provide a Schmitt trigger circuit with low-voltage devices. The proposed Schmitt trigger circuit can receive the high-voltage input signal but it is consisted by only using the low-voltage devices with thin gate oxide. For example, it is implemented in a 0.13 μm 1V/2.5V Complementary Metal-Oxide Semiconductor (CMOS) process. However, it can be operated in the 3.3V interface environment without causing the high-voltage-induced gate-oxide reliability problem. It is suitable for the I/O interface circuit to receive the high-voltage input signal and to reject the noise.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

FIG. 1 is a schematic drawing of a conventional input buffer depicting that the input buffer uses a Schmitt trigger circuit to receive the input signal and then uses a level converter to convert the signal swing from VCC to VDD

FIG. 2A is a schematic diagram depicting the circuitry of the conventional Schmitt trigger circuit.

FIG. 2B shows the transfer curve of the Schmitt trigger circuit of FIG. 2A.

FIG. 3 is a schematic diagram depicting the circuitry of a Schmitt trigger circuit with controllable hysteresis according to prior arts.

FIG. 4 is a schematic diagram depicting the circuitry of a two layers Schmitt trigger circuit according to prior arts.

FIG. 5 is a circuitry of a Schmitt trigger circuit depicting a preferred embodiment of the present invention.

FIG. 6 shows the simulation waveforms of signals IN and B.

FIG. 7A shows the simulation waveform of signal IN according to the Schmitt trigger circuit of FIG. 5.

FIG. 7B shows the simulation waveforms of signal A and B according to the Schmitt trigger circuit of FIG. 5.

FIG. 7C shows the characteristic curve of the simulation waveform of signal OUT according to the Schmitt trigger circuit of FIG. 5.

FIG. 8 shows the simulation transfer curve of the Schmitt trigger circuit according to the present invention.

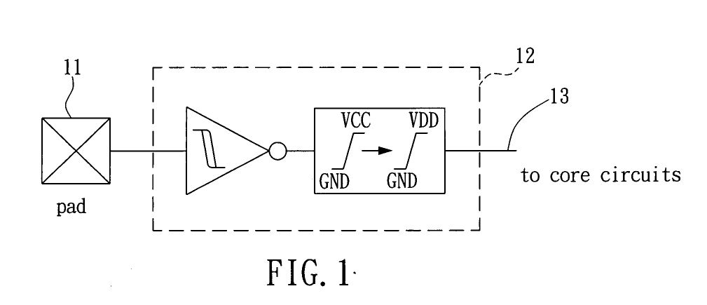

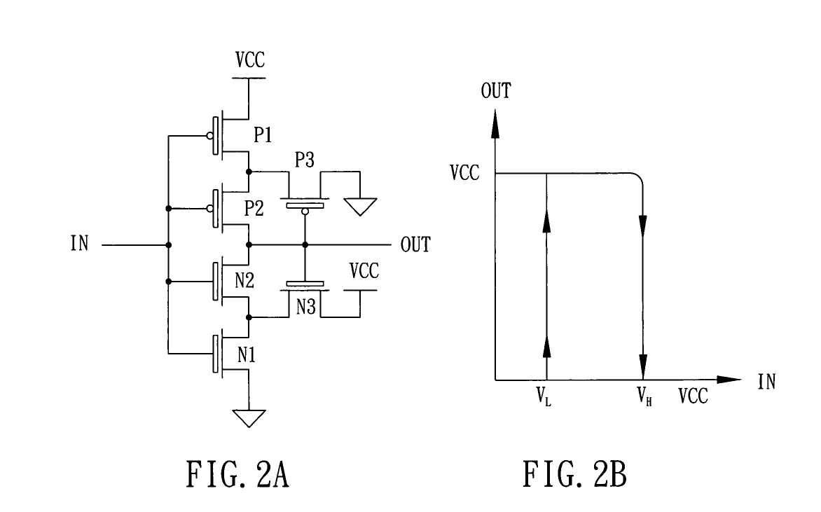

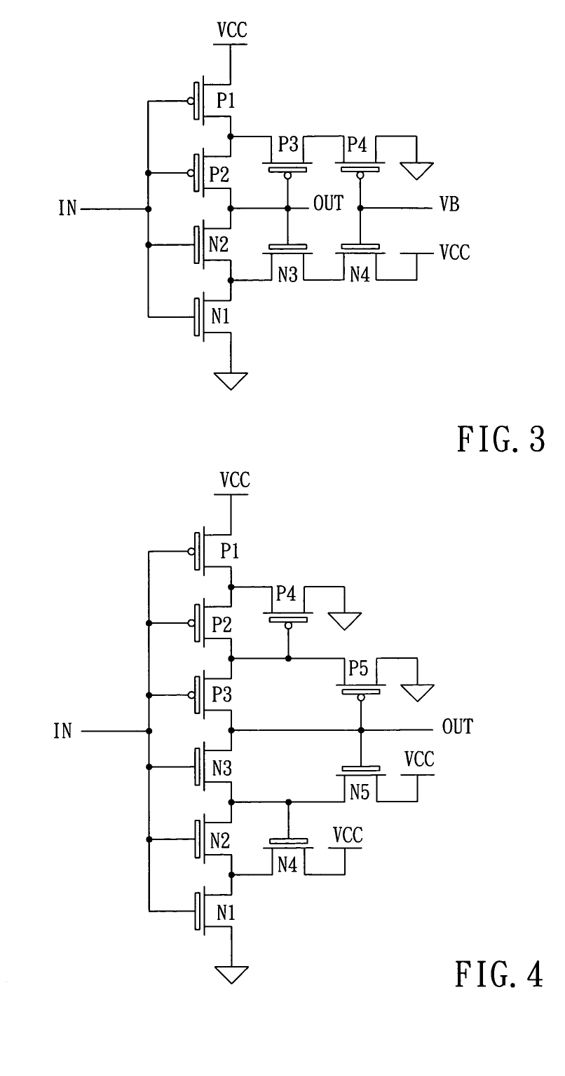

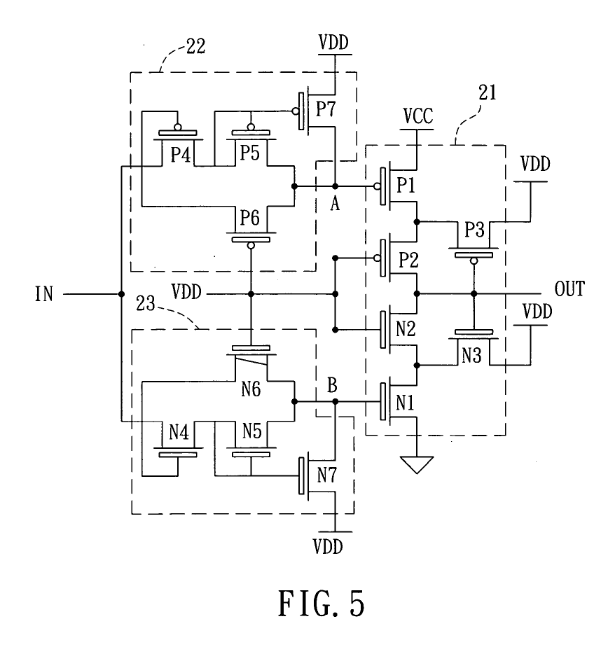

### DESCRIPTION OF THE PREFERRED EMBODIMENT

The proposed Schmitt trigger circuit of the present invention can receive the high-voltage input signal but it is consisted by only using the low-voltage devices with thin gate oxide. For example, it can be implemented in a 0.13 μm 1V/2.5V Complementary Metal-Oxide Semiconductor (CMOS) process. However, it can be operated in the 3.3 V interface environment without causing the high-voltage-induced gate-oxide reliability problem. It is suitable for the I/O interface circuit to receive the high-voltage input signal and to reject the noise.

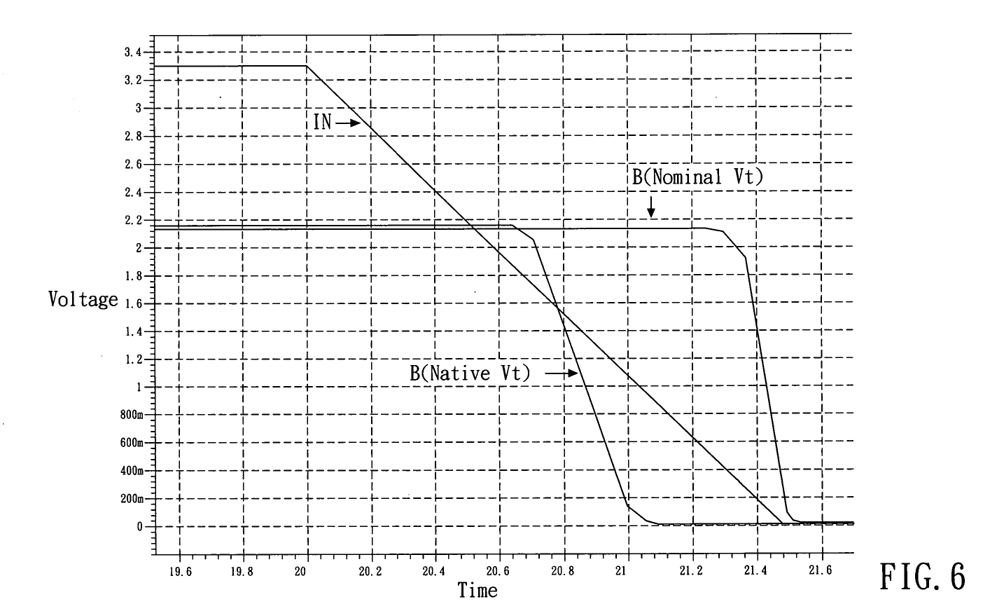

Please refer to FIG. 5, which is a circuitry of a Schmitt trigger circuit depicting a preferred embodiment of the present invention. As shown, the Schmitt trigger circuit comprises a main circuit 21, a first protection circuit and a second protection circuit. The main circuit 21 is composed of three P-type and three N-type MOSFETs, which are P1, P2, P3, N1, N2, and N3, and the operations of the main circuit is controlled by a node A and a node B; the first protection circuit 22 is composed of four P-type MOSFETs, which are P4, P5, P6, and P7, for ensuring the source-gate voltage of P1 can be smaller than VDD; the second protection circuit 23 is composed of four N-type MOSFETs, which are N4, N5, N6, and N7, for ensuring the source-gate voltage of N1 can be small than VDD. Moreover, all devices are I/O (VDDQ) devices. In a 0.13 μm 1V/2.5V CMOS process, VDDQ is 2.5V and VDD is 1V. Because the drains of the transistors P3 and N3 are connected to 1V (VDD), the gate-drain voltages of the transistors P3 and N3 will not exceed 2.5V. The maximum gate-drain voltages of the transistors P3 and N3 are about 2.3V (i.e. 3.3V−1V=2.3V). Because the gates of transistors P2 and N2 are connected to 1V (VDD), the gate-drain and gate-source voltages of transistors P2 and N2 will not exceed 2.5V, and the maximum thereof are also about 2.3V. If the gate voltage of transistor P1 (node A) is larger than 0.8V (3.3V−2.5V=0.8V), and the gate voltage of transistor N1 (node B) is smaller than 2.5V, the transistors P1 and N1 don't have the high-voltage gate-oxide problem. Thus, the first protection circuit (i.e. transistors P4, P5, P6, and P7) prevents the gate voltage of transistor P1 under 0.8V, and the second protection circuit (i.e. transistors N4, N5, N6, and N7) prevents the gate voltage of transistor N1 over 2.5V.

As signal IN is at 3.3V (VCC), node A is also at 3.3V since transistors P6 is turned on. As signal IN reaches 0V, node A is at 2|Vtp| because transistors P4 and P5 are diode-connected structure transistors. |Vtp| is the threshold voltage of VDDQ nominal Vt PMOS transistor. In the 0.13 μm 1V/2.5V CMOS process, |Vtp| is about 0.6V. Therefore, the minimum gate voltage of transistor P1 (node A) is about 1.2V. However, the diode-connected transistors P5 and P6 may make node A to 0V as signal IN stays at 0V a long time because of the subthreshold current of transistors P5 and P6. AN extra transistor P7 is added to prevent node A over 1V induced by the subthreshold current of transistors P5 and P6. As node A is under 1V, transistor P7 is turned on to keep the voltage at 1V.

As signal IN is at 0V, node B is also at V because the transistor N6 is turned on. As signal IN goes to 3.3V, node B is at 3.3V−2|Vtn| because transistors N4 and N5 are diode-connected structure transistors. |Vtn| is the threshold voltage of VDDQ nominal Vt NMOS transistor. In the 0.13 μm 1V/2.5V CMOS process, |Vtn| is about 0.5V. Therefore, the maximum gate voltage of transistor N1 (node B) is about 2.3V. However, the diode-connected transistors N5 and N6 may make node B to 3.3V as signal IN stays at 3.3V a long time because of the subthreshold current of transistors N5 and N6. A weak transistor N7 is added to prevent node B over 2.5V induced by the subthreshold current of transistors N5 and N6. As node B goes to 3.3V, transistors N7 provides a small current to keep the gate voltage of transistor N1 under 2.5V. Besides, transistor N6 is a 2.5V native Vt transistor. Because the gate source voltage of transistor N6 is so small that node B follows signal IN to 0V slowly.

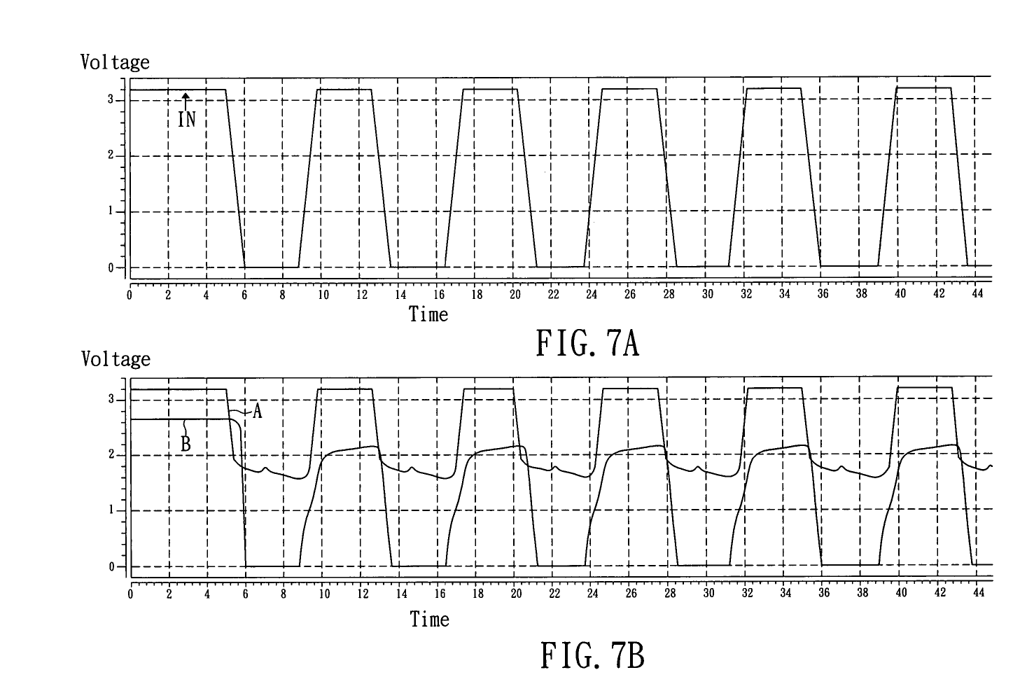

Please refer to FIG. 6, which shows the simulation waveforms of signals IN and B. As seen, the difference is obvious comparing the transistor N6 is a native Vt transistor and the transistor N6 is a nominal Vt transistor. It shows that node B is pulled down quickly as transistor N6 is a native Vt transistor.

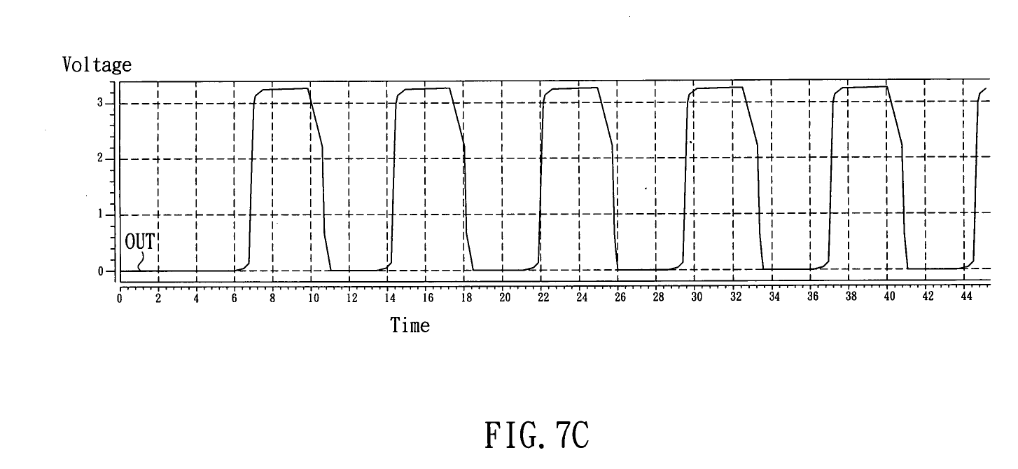

FIGS. 7A, 7B, and 7C show the simulation waveform of signal IN, signal B, and signal OUT according to the Schmitt trigger circuit of FIG. 5, in respective. Wherein, signal A is higher than 0.8V and signal B is lower than 2.5V.

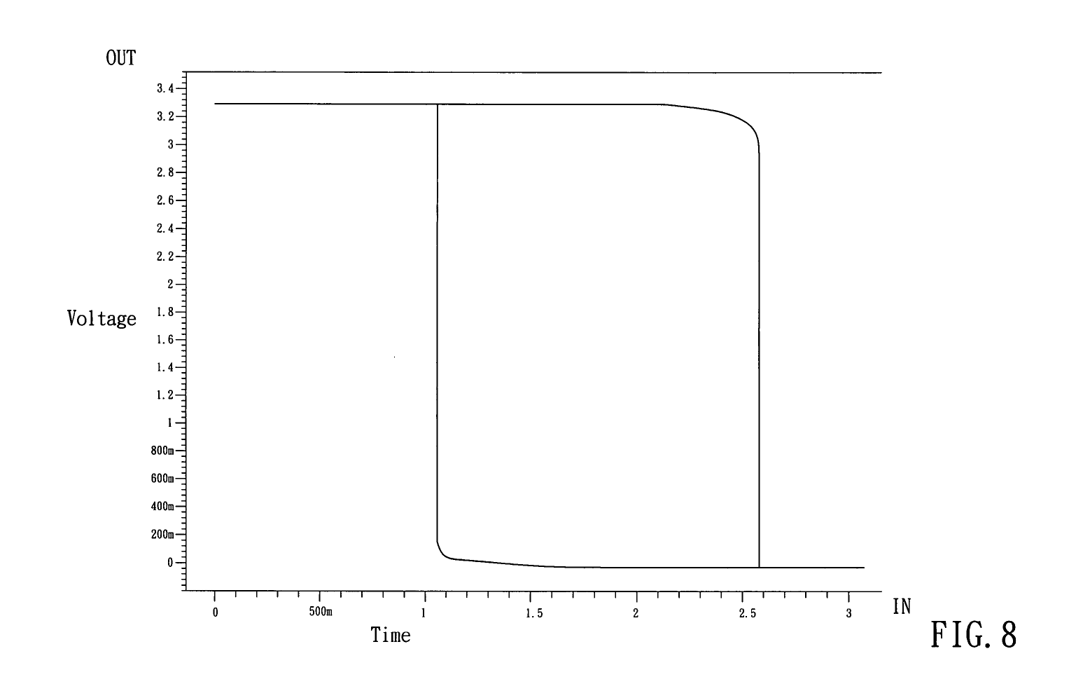

FIG. 8 shows the simulation transfer curve of the Schmitt trigger circuit according to the present invention. It has hysteresis characteristics. In this simulation, V_{H} is about 2.05V and V_{L} is about 1.05V.

From the description disclosed in FIG. 5 to FIG. 8, the present invention provides a Schmitt trigger circuit capable of receiving a high-voltage input signal, but being consisted by only using low-voltage devices with thin gate oxide. The present invention adapts a plurality of serial-connected Metal-Oxide Semiconductor Field Effect Transistors (MOSFET) to form a low-cost Schmitt trigger circuit capable of enduring 3.3V, instead of 2.5V.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

Therefore, the aforementioned description is just several preferable embodiments according to the invention and, of course, can not limit the executive range of the invention, so any equivalent variation and modification made according to the claims claimed by the invention are all still belonged to the field covered by the patent of the present invention. Please your esteemed members of reviewing committee examine the present application in clear way and grant it as a formal patent as favorably as possible.

1. A Schmitt trigger circuit with low-voltage devices, capable of receiving a high-voltage input signal, but being consisted by only using low-voltage devices, adapting a plurality of Metal-Oxide Semiconductor Field Effect Transistors (MOSFET) to form a low-cost Schmitt trigger circuit, comprising:
a main circuit 21, being composed of three P-type and three N-type MOSFETs, and the operation thereof being controlled by the voltage over a node A and a node B;
a first protection circuit, being composed of four P-type MOSFETs, for ensuring the voltage at the node A is larger than a specified low voltage value; and
a second protection circuit, being composed of four N-type MOSFETs, for ensuring the voltage at the node B is smaller than a specified high voltage value.

2. The Schmitt trigger circuit of claim 1, wherein the maximum voltage receivable by the plural MOSFETs is 2.5V.

3. The Schmitt trigger circuit of claim 1, wherein the specified low voltage value is 0.8V.

4. The Schmitt trigger circuit of claim 1, wherein the specified high voltage value is 2.5V.

5. The Schmitt trigger circuit of claim 1, wherein one of the N-type MOSFETs in the second protection circuit is a native Vt MOSFET.
